(19) United States
(12) Patent Application Publication
(10) Pub. No.: US 2019/0067500 A1
(43) Pub. Date: Feb. 28, 2019

(54) Quantum NPS Photodetector

(71) Applicant: Georgio Di Papa, Irvine, CA (US)

(72) Inventor: Georgio Di Papa, Irvine, CA (US)

(73) Assignee: Quantum Nanophotonics LLC, Irvine, CA (US)

(21) Appl. No.: 16/013,043

(22) Filed: Jun. 20, 2018

Related U.S. Application Data
(60) Provisional application No. 62/551,105, filed on Aug. 28, 2017.

(51) Int. Cl. H01L 31/0352; H01L 31/0232

(52) U.S. Cl. CPC H01L 31/035209; H01L 31/02327

(57) ABSTRACT

This invention describes a Quantum NPS Photodetector (QNPSPD). A plurality of dispersed patterned Nanoporous Silicon island regions with sub 50 nm pore nc-pSi nanostructure are formed in a high resistivity Si substrate on the first side of a front illuminated QNPSPD device with each nc-pSi region surrounded along its perimeter by a contiguous interconnected p/n diode junction. The Quantum NPS Photodetector is characterized by enhanced responsivity in the spectral range of from about 0.2 um to about 1.1 um, low noise, and fast response time, and it can operate from 10 mV to about 180V. The QNPSPD photodetector can provide excellent imaging in the UV-VIS-NIR spectral range that is important for many applications including defense, homeland security, medical imaging, and night vision. The QNPSPD manufacturing method described is adaptable for low cost manufacturing and scalable to large size wafer diameters. Various embodiments of the Quantum NPS Photodetector and methods for its manufacturing are disclosed.

### PRIORITY DATA

This application claims the benefits of U.S. Provisional Patent Application Ser. No. 62/551,105, filed on Aug. 28, 2017, which is incorporated herein by reference.

### BACKGROUND OF THE INVENTION

### 1. Field of the Invention

The present invention relates to novel device structures of Quantum Nanoporous Silicon Photodetector (QNPSPD) and methods for configuring and constructing the same.

### 2. Prior Art

Conventional photodiode structures are based on either front or back illuminated technologies using predominantly a Silicon (Si) substrate. FIG. 1 illustrates key components of a typical legacy commercially available (prior art) front illuminated 0.4 um-1.1 um VIS-NIR NIP Silicon (Si) Photodetector structure 50, made on N<111> type high resistivity Silicon substrate 1 with a thickness range of from about 300 um to about 450 um with or without a surface texturization option on either side of the substrate. Diffusion of a second conductivity type is applied on first side 2 in region 6 to form a p/n junction diffused to a depth range of from about 0.5 um to about 1.5 um. The second side 4 is doped with a dopant of first conductivity type via either ion implantation and/or Planar Solid Source dopant deposition to form a heavily doped back surface field (BSF) region 5 with a doping concentration of greater than or equal to about 10e19/cm³. Metal contacts 8 are deposited and patterned on the first side 2 of the second conductivity type region 6 via pattern openings in an antireflection layer coating (ARC) layer with a silicon dioxide (SiO₂) passivating surface interface 7 with the ARC coating optimized for short NIR responsivity peak at about 950 nm and with minimum incident light surface reflectance at 1064 nm to about equal or less than 2%. A tri-metal layer scheme 9 is deposited on the second side 4 with an interface Aluminum layer for back reflectance to enhance responsivity at about 1064 nm followed typically by a Cr adhesion middle layer and a bottom Au layer for eutectic bonding on gold plated assembly material surfaces like a TO Header. This legacy high resistivity nearly intrinsic hyper pure Si VIS-NIR PIN Photodetector device typically operates at a high reverse bias range of from about 50V to about 180V depending on responsivity range of interest and the high resistivity silicon layer thickness utilized by design as dictated by the photodetector application specification requirements.

Surface texturization is typically applied to the back side of the Photodetector to enhance the responsivity at 1064 nm via light multi pass trapping properties due to internal back light reflection, light scattering, and refraction. Legacy commercial Si based NIR photodetectors are constrained to light sensitivity of about 1.1 um due to the cut-off wavelength of crystalline Si as a result of its indirect Band Gap energy of about 1.12 eV. In such a legacy Photodetector (PD) structure, control of responsivity enhancement at 1064 nm has a significant variance based on the quality of the back surface tri-metal NIR mirror and second side Si surface roughness control. In addition a dual antireflection coating (ARC) is optimized for NIR wavelengths of greater than or equal to about 950 nm by compromising on optimum response and a lower QE in the Visible and Short NIR range of from about 400 nm to 800 nm.

An advantage of using a very high resistivity Si based substrate platform to construct a Photodiode is due to the very high minority carrier lifetime of about equal or greater than 100 usec and a very low defect density that such a material is characterized when ingots are grown using a Float-Zone (FZ) method or equivalent Ultra-High-Purity (UHP) growth method also known as Hyper Pure Silicon (HPS) as compared to low resistivity Si material. The deeper “depletion depth” electric field with reverse bias that can be attained with high resistivity material is also an additional advantage for fast response time PD performance as NIR photogenerated carriers are collected via “drift” in the depletion field. This allows for a large variety of legacy Silicon based photodetector active area sizes and multi-element PD arrays to be made with a PD active area element design of from about 0.5 mm² to well over 100 mm² characterized by a high wafer yield with moderately low dark current in the nA range, low Noise Equivalent Power (NEP), and high Signal-to-Noise-Ratio (SNR), covering a responsivity range of from DUV at about 200 nm to short NIR at about 1064 nm with a cut-off wavelength at about 1.1 um.

Porosification of silicon has been explored for over 30 years mostly for its very high surface area used for many applications like energy conversion (batteries, fuel cells, solar cells), medical (drug delivery), to name a few. Other applications include porous Si use as an antireflection layer in Solar Cells, in micro optics as a filter, mirror, diffraction gratings, and it is also used in waveguides and modulator applications. In active optoelectronics devices nanoporous Si use has been limited to LED's, and LASER's, utilizing its optical properties and photoluminescence properties in visible-red light spectrum due to nanoporous Si quantum confinement properties in the nanocrystals of silicon present within the pores and pore walls, but such interest has slowed down in recent years.

The predominant work on porosification has been focused on low resistivity silicon in the 1-20 ohm·cm as it could be easily porosified. There is no relevant work known to the inventor today that has explored the use of selective silicon porosification to form Nanoporous Si structures for low noise, fast response time Photodetector device applications utilizing high resistivity silicon substrates, with resistivity of about equal or greater than 1,000 Ohm·cm for sensor and imaging applications in the 200 nm-1,100 nm range with enhanced UV-VIS-NIR PD responsivity.

In more recent years, efforts were concentrated in raising the responsivity of Si Photodetectors utilizing surface texturization of the front p/n junction side and/or back surface depending on the peak wavelength of interest to minimize reflection and increase light absorption in the substrate due to light trapping. Such texturization efforts include “Surface Microstructuring” utilizing a laser assisted silicon chemical etch process with incorporation of Sulfur dopant for enhanced responsivity gain in the Visible and short NIR spectral range and/or incorporating such texturization in device structures that include wafer bonding is described in prior art from other inventors for responsivity gain enhancements. See for example Optics Letters: Vol. 30, No. 14, 1773, 15 Jul. 2005, Applied Physics Letters: 89, 033506, 2006, U.S. Pat. Nos. 8,846,551 B2, 9,673,250 B2. Such devices are reported to extend the Si cutoff wavelength to about 1.5 um but have low sensitivity beyond 1.1 um, and can also suffer from potential “device instability” under continuous operating conditions below 0.4 um in the UV and DUV range, as well as above 1.1 um due to accelerated device degradation of its laser microstructure Si oxidized surface doped with Sulfur and/or other equivalent chalcogenide based incorporated elements. Such surface microstructured Photodetector devices are also characterized by high leakage currents, high Noise Equivalent Power (NEP), and slow PD response time due to the surface microstructuring incorporation within the active p/n junction region of the PD creating defects that have an immediate impact on the PD DC electrical performance, while also working on lower resistivity Si material mostly for CMOS type of imaging applications.

The novel Quantum Nanoporous Silicon Photodetector (QNPSPD) device design structures described herein can be considered an alternative art to legacy high resistivity PIN Si Photodetectors and Surface Microstructure Silicon Photodetectors of prior art, utilizing selective porosified isolated Nanoporous Silicon (NPS) pattern island region structures on the first side (p/n junction side) of the QNPSPD device forming a photosensitive “Quantum Continuum” effective light absorbing region in the QNPSPD Photodetector in a high resistivity hyper pure silicon substrate of greater than or equal to about 1,000 Ohm·cm with wafer thickness of greater than or equal to about 300 um for low noise fast response time Photodetector performance with enhanced responsivity in the 0.2 um to 1.1 um spectral range utilizing construction methods that are scalable to large diameter wafer sizes for low cost commercialization. The QNPSPD device structure can be customized with device design optimization for photodetection capability in the 0.2 um to 1.55 um spectral range.

### Definitions

The following terminology will be used in accordance with the definitions cited below.

As used herein, the term “PD” refers to Photodetector.

As used herein, the term “APD” refers to Avalanche type Photodetector.

As used herein, the term “PIN” refers to a P-type p/n junction Anode region formed in an n-type Intrinsic Silicon substrate with an N-Type Cathode region. Similarly, the term “NIP” refers to an N-type n/p junction Cathode region formed in a p-type Intrinsic Silicon substrate with a P-Type Anode region.

As used herein, the term “Anode” refers to Acceptor dopant type regions with positive charge majority carriers.

As used herein, the term “Cathode” refers to Donor dopant type regions with negative charge majority carriers.

As used herein, the term “c-Si” refers to crystalline silicon.

As used herein, the term “NPS” refers to “nanoporous silicon” and nanoporous morphology structures with pores having an irregular short-range order nanocrystalline structure with randomly interconnected nanocrystalline wires with a c-Si wire skeleton width range of from about 0.5 nm to about 50 nm, unless otherwise noted.

As used herein, the term “nc-pSi” refers to nanocrystalline porous silicon with nanoporous structure and it is used interchangeably with the definition of NPS as needed to emphasize the impact of the nanocrystalline wire skeleton optoelectronic properties of nanoporous Si relating to its quantum confinement effects.

As used herein, the term “nc-Si” refers to the nanocrystalline silicon skeleton of the randomly interconnected nanometer size range crystalline wires in the nanocrystalline porous Si structure characterized by optoelectronic properties of nanoporous Si relating to quantum confinement effects, and characterized by a pseudo direct bandgap (sub bandgap) level in addition to its c-Si indirect bandgap property.

As used herein, the term “first side” of the QNPSPD refers to the top side and/or the side wherein the p/n junction active region of the QNPSPD is formed, unless otherwise noted.

As used herein, the term “second side” refers to the back side of the QNPSPD device, unless otherwise noted.

As used herein, the term “porosification” refers to porous structures formed by anodic electrochemical etching of the high resistivity silicon substrate, with pores that include nanopores and/or macropores with pore sizes ranging from of about 0.5 nm to about 50 um unless otherwise noted.

As used herein, the term “HPS” refers to high resistivity Hyper Pure Silicon derived by any Ultra High Purity Ingot growth method including but not limited to Float Zone Silicon (FZ-Si) growth.

As used herein, the coined term “Quantum NPS Photodetector” (QNPSPD) is used in some embodiments of this disclosure to define a front side illuminated Photodetector with porosified regions on the front side and/or back side of the Photodetector consisting of a single nanoporous NPS layer and/or a plurality of Nanoporous region structures, wherein the porosified NPS region structures exhibit quantum confinement properties with tunable bandgap properties characterized by pseudo direct bandgap and indirect bandgap light absorption properties.

As used herein, the coined term “Quantum Continuum” effective light absorbing region refers to the total QNPSPD Photodetector effective volumetric active regions of the QNPSPD device illuminated by a light beam of a given size that impinges directly on the p/n junction diode effective active area region, including the intrinsic high resistivity light absorbing region, the surrounding porosified NPS island regions formed in the high resistivity Si semiconductor substrate, and including any NIR light impinging the porosified nanoporous regions that might be present on the second side, with any and all porosified regions characterized by quantum confinement properties. As such, the NPS island regions in the QNPSPD device described in this invention are considered to be optoelectronically active regions with “quantum optoelectronic properties” contributing to the enhancement of the total photocurrent output of the QNPSPD device from incident light impinging on any such regions.

As used herein, the term “Volumetric” refers to the semiconductor volume per each cubic um present within the Photodetector optoelectronically active regions, including the p/n junction diode effective active area region, the intrinsic high resistivity light absorbing region, the surrounding porosified NPS island regions formed in the high resistivity Si semiconductor substrate, and any porosified nanoporous regions that might be present on the second side.

As used herein, the term “Space Charge Region” (SCR) width (w) refers to the depletion layer width of the high resistivity Si substrate semiconductor and it can be calculated using the semiconductor's built-in voltage Vbi, the number of ionized donors Nd and acceptors Na respectively, based on the substrate type and resistivity used. One expression for the Space Charge Region Width “w” is shown in Equation I, where “q” is the charge of an electron, “ϵr” is the relative dielectric permittivity of the semiconductor, “V” is the applied reverse bias, and ϵ₀=8.854×10⁻¹² F/m, where “F” is Farad and “m” is meter.

$$w = {[ \frac{2 {ɛ}_{r} {ɛ}_{o}}{q} \frac{( Na + Nd )}{NaNd} ( Vbi - V ) ]}^{1 / 2} \qquad ( I )$$

As used herein, the term “Noise Equivalent Power” (NEP) refers as the measure of the sensitivity of the photodetector. A smaller NEP corresponds to a more sensitive photodetector. The NEP is equal to the photodetector noise current divided by the responsivity of the photodetector at the peak wavelength of interest. One expression for the Noise Equivalent Power (NEP) is shown in Equation II, where

$$NEP ( \frac{W}{√ Hz} ) = \frac{Noise Current ( \frac{A}{√ Hz} )}{Responsivity ( \frac{A}{W} )} \qquad ( II )$$

where “A” is Amps, “Hz” is Hertz, and “W” is Watts.

As used herein, the term “contiguous interconnected region” refers to a continuous region that surrounds a plurality of smaller disposed dispersed island regions along each island region perimeter without making direct contact to each disposed island region.

As used herein, a “plurality” of structural elements should be interpreted as each member of the structural element is individually identified as a separate and unique member.

As used herein, the singular “a”, and, “the” can include a plural reference unless the context clearly dictates otherwise. For example, reference to “a dopant” can include one or more of such dopants and reference to “the layer” can include reference to one or more such layers.

As used herein, a “dopant” can be either a Donor or Acceptor dopant species, or neutral charge species. Thus, as an example but not limited to, a dopant species can include P, B, As, Sb, Ar or equivalent element species unless it is explicitly specified otherwise.

As used herein, the term “BSG” refers to BoroSilicateGlass deposited on the Si surface in a non-limiting PDS “vapor transfer” method and/or a non-limiting CVD method, and it is used as a constant Boron doping source.

As used herein, the term “PSG” refers to PhosphoSilicateGlass deposited on the Si surface in a non-limiting PDS “vapor transfer” method and/or non-limiting CVD method, and it is used as a constant Phosphorous doping source.

As used herein, the term “PDS” refers to Planar Diffusion Source also known as Solid State Disc (SSD).

As used herein, the term “Responsivity” is the input-output gain of a photodetector expressed in amps per watt of incident light radiant power, and it is a function of the wavelength of incident radiation, and several material properties that include but not limited to surface reflectance, and electronic bandgap property of the material of which the photodetector is made, including minority carrier collection efficiency.

As used herein, the term “enhanced” is used to describe an increase in responsivity output gain magnitude of the QNPSPD Quantum Photodetector type described herein due to absorption of a greater percentage of light at a given wavelength in the Visible, and/or Red, and/or NIR spectral range due to quantum confinement properties, and/or mid band gap absorption properties (MBA), and/or two photon absorption (TPA) properties of the nanoporous structure, and/or light trapping properties of the porosified Nanoporous structure as compared to Photodetector devices of the same material and lacking porosified nanoporous and macroporous structure regions as defined herein.

As used herein, the term “TPA” refers to Two Photon Absorption under high irradiance when a high power (>0.2 W) light source is used with a short Pulse Width in the 200-400 fsec range.

As used herein, the term “MBA” refers to Mid Band Gap light Absorption caused by modification of the band structure due to the presence of interstitial site defects creating energy levels within the nanocrystalline Si bandgap of the NPS morphology structures.

As used herein, the term “light trapping” is used to describe the internal “multi pass” of light of a given wavelength within the substrate of the Photodetector regardless of wafer thickness due to internal reflection and scattering in the NPS morphology structure regions of the Quantum NPS Photodetector type described herein, increasing the effective path distance travelled by the light within the Photodetector active region and thus increasing the probability of a higher percentage of light of a given wavelength getting absorbed prior to exiting the substrate.

As used herein, the term “tuning” refers to selectively modifying the morphology and/or doping of the NPS regions of the QNPSPD for enhanced absorption of light at a desired wavelength or range of wavelengths. In one aspect, band gap tuning in the Nanoporous morphology structure will result to modified band gap properties of nanoporous Silicon extending light absorption at NIR wavelengths beyond 1.1 um.

As used herein, the term “about” is used to describe that a given number might be “slightly above” or “slightly below” the endpoint.

As used herein, the term “range” should be interpreted to include not only the numerical values explicitly recited as the limit of the range, but also include all the individual numerical values within that range as if each numerical value is explicitly recited.

As used herein, the term Quantum Efficiency “QE” refers to the “IQE” Internal Quantum Efficiency of the Photodetector.

As used herein, the term “IQE” refers to the Internal Quantum Efficiency of the Photodetector, as being the number of charge carriers collected by the photodetector divided by the number of incident photons absorbed by the Photodetector.

As used herein, the term “EQE” refers to the External Quantum Efficiency of the Photodetector, as being the number of charge carriers collected by the photodetector producing a photocurrent divided by the number of incident photons per second impinging on the surface of the Photodetector.

As used herein, the term “response time” is the time it takes for the photodetector to respond to an optical input, consisting of a “rise time” and “fall time”. “Rise time” is the time difference between the 10% and 90% level of the peak amplitude output on the leading edge of the electrical signal generated by the absorbed light in the photodetector, and “fall time” is the time difference between the 90% and 10% level of the trailing edge of the electrical signal.

As used herein, the term “DUV” light refers to the Deep Ultraviolet Light Spectrum range of from about 100 nm to about 200 nm.

As used herein, the term “UV” light refers to the Ultraviolet Light Spectrum range of from about 200 nm to about 380 nm.

As used herein, the term “BLUE” light refers to the Violet-Blue Light Spectrum range of from about 380 nm to about 495 nm.

As used herein, the term “VISIBLE” or “VIS” refers to the entire eye Visible Light Spectrum range of from about 380 nm to about 750 nm, but with more emphasis in the 495 nm to750 nm range.

As used herein, the term “RED” refers to the Red Light Spectrum range of 620 nm-750 nm.

As used herein, the term “NIR” refers to the Near Infra Red Light Spectrum range of from about 750 nm to about 1,400 nm unless otherwise noted.

As used herein, the term “short-NIR” refers to the Near Infra Red Light Spectrum range of from about 750 nm to about 1064 nm unless otherwise noted.

As used herein, the term “UV-VIS” refers to the Light Spectrum range of from about 200 nm to about 750 nm unless otherwise noted.

As used herein, the term “VIS-NIR” refers to the Light Spectrum range of from about 400 nm to about 1,400 nm unless otherwise noted.

As used herein, the term “ARC” refers to Anti Reflection Coating layer typically comprised of a dielectric thin film that includes Silicon Dioxide and/or Silicon Nitride to minimize surface reflection of the incident light impinging the surface of the Photodetector.

As used herein, the term “RTO” refers to Rapid Thermal Oxide formed using a Rapid Thermal processing System in a gas ambient that includes oxygen.

As used herein, the term “RTONx” refers to Rapid Thermal Nitrided Oxide formed using a Rapid Thermal processing System in a gas ambient that includes oxygen and nitrous oxide.

As used herein, CVD refers to Chemical Vapor Deposition, including but not limited to Rapid Thermal CVD (RTCVD), Plasma Enhanced CVD (PECVD), Atmospheric Pressure CVD (APCVD), and Low Pressure CVD (LPCVD).

As used herein, the term “LIDAR” (also called Lidar) refers to Light Imaging Detection and Ranging, and it is a surveying method that measure the distance to a target by illuminating the target with a pulsed laser light and measuring the reflected pulses with a sensor.

As used herein, the term “ROIC” refers to Read Out Integrated Circuit.

As used herein, the term “ASIC” refers to Application Specific Integrated Circuit.

As used herein, the term “PIC” refers to Photonic Integrated Circuit.

As used herein, the term “TO” refers to a designation for a standard metal semiconductor package standing for “Transistor Outline” and relates to a series of technical drawings produced by JEDEC (Joint Electron Device Engineering Council).

### SUMMARY

This invention provides structures of Quantum Nanoporous Silicon Photodetector (QNPSPD) devices manufactured on high resistivity Silicon with enhanced responsivity in the spectral range of from about 0.2 um to about 1.1 um, with low leakage current, low Noise Equivalent Power (NEP), fast response time, and methods for configuring and constructing the same.

In one aspect of the present disclosure, for example, a plurality of dispersed isolated patterned Nanoporous Silicon (NPS) array island regions are formed on the first side (p/n junction front illuminated side) of the Quantum NPS Photodetector (QNPSPD) via selective anodic electrochemical etch porosification of its top surface on a high resistivity Silicon (Si) substrate having a resistivity greater than about 1,000 Ohm·cm and crystal orientation of <100>, wherein each NPS island region is surrounded along its perimeter by a contiguous interconnected p/n junction diode region forming a photosensitive “Quantum Continuum” effective light absorbing region in the QNPSPD Photodetector.

The dispersed isolated nanoporous silicon array islands enable an enhanced Visible/Red Photodetector (PD) responsivity via downward photoluminescent light emission in the NPS island regions due to quantum confinement in the NPS sub 50 nm nc-pSi structure with nanocrystalline silicon skeleton and porosity in 0.5 nm-50 nm range, wherein the NPS regions are also characterized by increased light absorption in the short NIR due to specular and diffuse reflectance of incident light with multi pass light trapping properties.

The pattern distribution placement and size of the nc-pSi island regions allow for a low Noise Equivalent Power (NEP) device performance in the QNPSPD due to the separation gap distance placement design of the nc-pSi from the surrounding contiguous interconnected p/n junction, with QNPSPD device design parameters selected accordingly based on the high resistivity range of Si substrate utilized and given reverse bias as required by any given QNPSPD Photodiode performance specification application for a targeted wavelength range.

In another aspect of the present disclosure, the plurality of nanocrystalline porous Silicon (nc-pSi) structure island regions are surrounded by a passivated trench ring along each nc-pSi region perimeter providing electrical isolation from the electric field created from the surrounding p/n active junction and as such enabling under full bias depletion of the QNPSPD device a fast time response with low NEP for applications requiring enhanced responsivity performance with low noise in the short NIR range from about 850 nm to about 1.1 um under reverse bias. The QNPSPD device structure can be customized with device design optimization for photodetection capability in the 0.2 um to 1.55 um spectral range.

The device structures in this disclosure utilize construction methods that are scalable to wafer fabrication with large diameter wafer sizes including 150 mm Dia, 200 mm Dia, and 300 mm Dia, for low cost commercialization in an advanced high volume Photonics Wafer fabrication foundry and/or MEMS foundry fabrication facility for UV-VIS-NIR Quantum Nanoporous Si Photodetectors with low NEP and fast time response with enhanced responsivity and high QE from about 0.2 um to about 1.1 um.

The QNPSPD photodetector device structures described herein have a “Quantum Continuum” effective light absorbing region that is characterized by high quantum efficiency in UV/Visible/NIR spectrum range, fast PD response time, low leakage current, high shunt resistance, and low Noise Equivalent Power (NEP). The QNPSPD device in the present invention can be considered an enhanced performance PD alternative to typical legacy standard PIN Si Photodetector structures with or without surface roughness texturization, and/or laser assisted microstructured Silicon Photodetector, used in the Photonics and Optoelectronics sensor imaging industry for many applications including defense, homeland security, medical imaging, night vision, Lidar, and commercial imaging sensor applications, utilizing construction methods that are scalable to large diameter wafer sizes for low cost commercialization.

The QNPSPD device structures described in this disclosure can be monolithically integrated with PIC including waveguides, ROIC, and/or ASICS for sensitive low light signal imaging. Various embodiments of the Quantum NPS Photodetector device and methods for configuring and constructing the same are disclosed.

### BRIEF DESCRIPTION OF THE DRAWINGS

The main ideas of the invention are demonstrated by the accompanying Figure drawings, in which:

FIG. 1 illustrates key components of a typical legacy commercially available (prior art) high resistivity broadband 0.4 um-1.1 um VIS-NIR PIN Silicon (Si) Photodetector structure, with or without a surface texturization option on either side of the substrate.

FIG. 2 shows a cross section of an exemplary Quantum NPS Photodetector (QNPSPD) structure with front side trench isolated dispersed Nanoporous Silicon island regions surrounded by a contiguous interconnected p/n junction region, in accordance with one embodiment of the current invention.

FIG. 3A show top view example details of the first side of an exemplary QNPSPD device with a contiguous interconnected p/n junction region design surrounding a plurality of dispersed isolated Nanoporous Silicon (NPS) island regions with an exemplary non limiting NPS pattern distribution site placement and NPS size-shape, in accordance to several aspects of the present disclosure.

FIG. 3B show top view example expanded details of a contiguous interconnected p/n junction region design surrounding a plurality of dispersed isolated Nanoporous Silicon (NPS) island regions with an exemplary non limiting NPS pattern distribution site placement and NPS size-shape configuration with a trench ring isolation surrounding each NPS island region along its perimeter, in accordance to several aspects of the present disclosure.

FIGS. 4 through 9 show some detail aspects of an exemplary fabrication process sequence for configuring and constructing the QNPSPD structure shown in FIG. 2.

FIGS. 10 to 11 show other exemplary QNPSPD structures with trench isolated NPS island regions according to some embodiments of this invention, wherein the NPS island regions are formed at the end of the fabrication process flow following back metallization of the QNPSPD without NPS surface region passivation for low cost construction and compatibility for manufacturing at a typical wafer foundry fabrication facility on large size wafer diameter.

FIG. 12 shows yet another QNPSPD structure with trench isolated NPS islands regions, wherein the NPS regions formed at the end of the process flow are treated with RTONy rapid thermal passivation and utilizing metal ohmic contact schemes compatible with high temperature post processing exposure, in accordance with another embodiment of the current invention.

FIG. 13 shows another alternative QNPSPD structure with a contiguous interconnected pin photodiode active p/n junction region design surrounding a plurality of dispersed isolated Nanoporous Silicon (NPS) island regions without trenches, in accordance with one aspect of the present disclosure.

FIG. 14 shows yet another alternative QNPSPD structure with a contiguous interconnected p/n junction region design surrounding a plurality of dispersed isolated Nanoporous Silicon (NPS) island regions without trenches, wherein the NPS regions are formed at the end of the process flow following back metallization of the QNPSPD without NPS surface region passivation, in accordance with another aspect of the present disclosure.

FIG. 15 shows a further alternative QNPSPD structure with a contiguous interconnected p/n junction region design surrounding a plurality of dispersed isolated Nanoporous Silicon (NPS) island regions without trenches, wherein the NPS regions formed at the end of the process flow following back metallization of the QNPSPD are treated with RTONy rapid thermal passivation utilizing a metal ohmic contact scheme compatible with high temperature post processing exposure, in accordance with another aspect of the present disclosure.

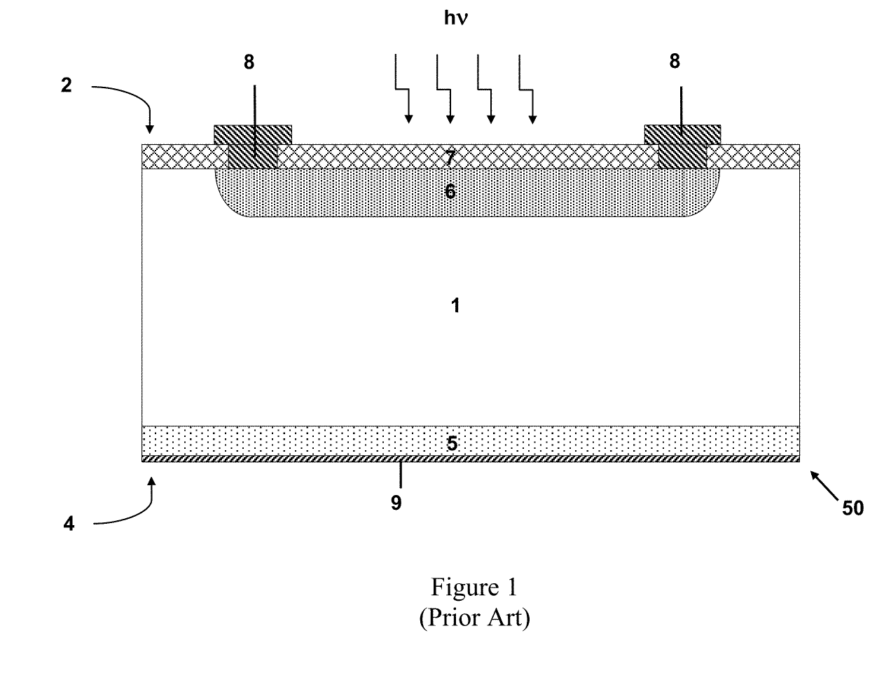

### DETAILED DESCRIPTION OF THE PREFERRED EMBODIMENTS

The objectives of the present invention include:

1) To provide Quantum Nanoporous Si Photodetector (QNPSPD) device structures in a high resistivity Silicon substrate for imaging and sensor applications.

2) To provide fabrication methods for the Quantum Nanoporous Silicon Photodetector (QNPSPD) device structures on high resistivity Si wafer substrates.

It is therefore an object of this invention to provide Quantum Nanoporous Si Photodetector (QNPSPD) structures that can operate in the 0.2 um-1.1 um spectral range with high QE and enhanced responsivity throughout the QNPSPD photodetection light spectrum range, low Noise Equivalent Power (NEP), and/or fast PD response time performance, operating in Photovoltaic and/or Photoconductive mode in a reverse bias range of from about 10 mV to about 180V for use in security, defense, night vision, Lidar, medical imaging, and industrial sensor applications.

These and other objects of the present invention will become apparent from the following disclosure when considered in conjunction with the accompanied Figures. In this disclosure, preferred embodiments of the Quantum Nanoporous Si Photodetector (QNPSPD) device structures and preferred methods of configuring and fabricating the Quantum Nanoporous Si Photodetector are described.

The design structure and properties of the Quantum Nanoporous Si Photodetector in the current invention are different than those of conventional Si PIN Photodetectors and/or microstructured Si Photodetectors that utilize Silicon substrates without the front patterned porosified sub 50 nm pore structures of dispersed isolated nc-pSi island regions formed within a surrounding contiguous interconnected p/n junction region in high resistivity silicon material.

The QNPSPD device structure can be made by a number of processes, depending on the desired application specifications and use, all of which should be considered to be within the present scope. A method of constructing a QNPSPD Photodetector device is provided.

In one aspect of the present disclosure, a high resistivity hyper pure silicon substrate of equal to or greater than 1,000 Ohm·cm is selectively porosified via a non limiting anodic electrochemical etching method on the first side forming a plurality of dispersed patterned nanocrystalline porous silicon (nc-pSi) island regions. The nanoporous Si (NPS) layer of the nc-pSi island regions has a thickness (depth) range of from about 0.1 um to about 50 um with NPS porosity of from about 0.5 nm to about 50 nm and nc-pSi wire skeleton with c-Si width range of from about 0.5 nm to about 50 nm with a contiguous interconnected p/n junction region surrounding each nc-pSi island region geometrical shape along its perimeter forming a “Quantum Continuum” effective light absorbing region.

In another aspect of the present disclosure, the plurality of dispersed nanocrystalline porous Silicon (nc-pSi) island regions in the NPS layer are surrounded by a passivated trench ring along each nc-pSi region perimeter providing electrical isolation from the electric field created from the surrounding p/n active junction region of the QNPSPD under reverse bias.

In a further aspect of the present disclosure, an alternate method forms the plurality of dispersed isolated NPS islands regions at the end of the Photodector manufacturing process flow following back metallization of the QNPSPD without NPS surface region passivation for low cost construction and compatibility for manufacturing at a typical wafer foundry fabrication facility.

In yet another aspect, the method can also include post heat treatment with rapid thermal (RTONy) nitrided oxide passivation (SiOxNy) of the nc-pSi regions at the end of the fabrication process flow while utilizing front metal ohmic contact schemes compatible with high temperature post processing exposure, to provide QNPSPD device stability under continuous operation in the UV, Blue, and Red response.

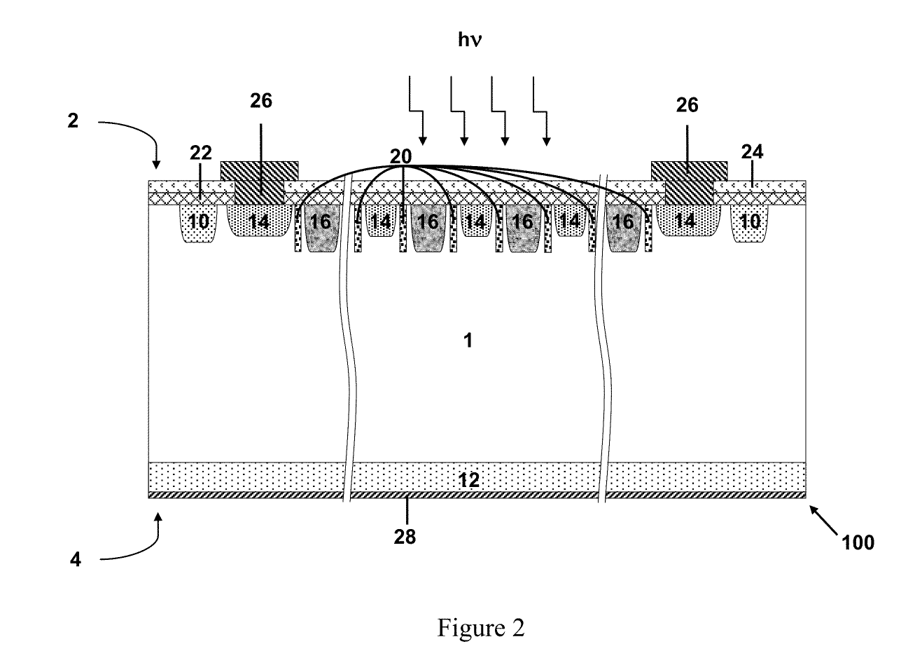

The embodiments of the present invention are shown in and described with respect to FIGS. 2 through 15.

FIG. 2 shows a first example of a Quantum Nanoporous Si Photodetector (QNPSPD) device structure cross section in accordance with the present invention.

The QNPSPD Photodetector device structure 100 shown in FIG. 2 is a front surface illuminated photodetector and it is made using a high resistivity hyper pure crystalline silicon (c-Si) substrate 1 of a first conductivity type with thickness range of from about 250 um to about 650 um and silicon resistivity range of from about 250 Ohm·cm to about 20,000 Ohm·cm having VIS-NIR light absorbing properties. P-Type Silicon (Si) substrates of <100> crystal orientation are preferred as porosification of high resistivity conductivity P <100> Si is more adaptable to anodic electrochemical etching for controlled formation of the nanocrystalline porous silicon (nc-pSi) structure properties. P-type Si is also characterized by a faster response drift time in NIR Si Photodetector applications as the photogenerated minority carriers are electrons having about three times higher mobility than holes. However, N-Type high resistivity Si substrates and/or <111> Si crystal orientation can alternatively be used as well.

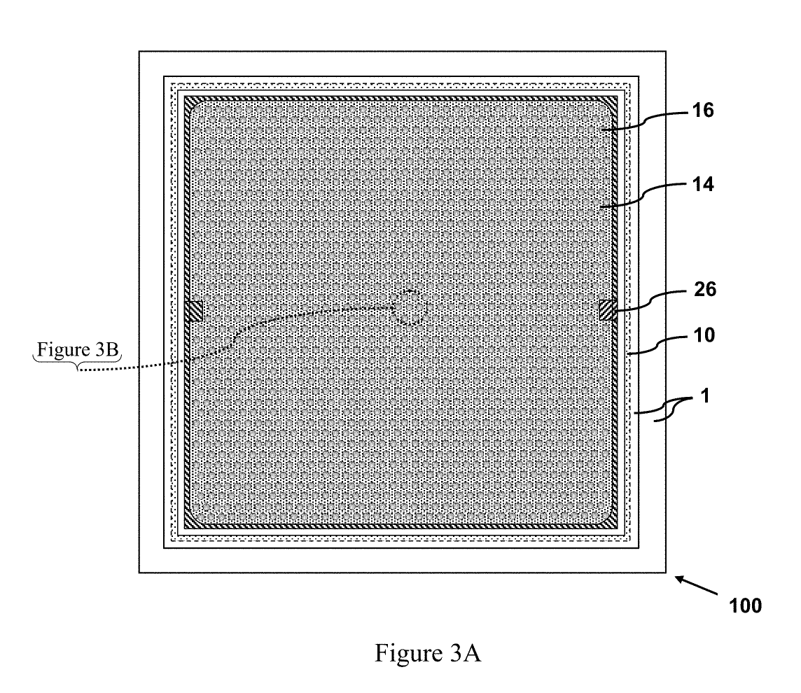

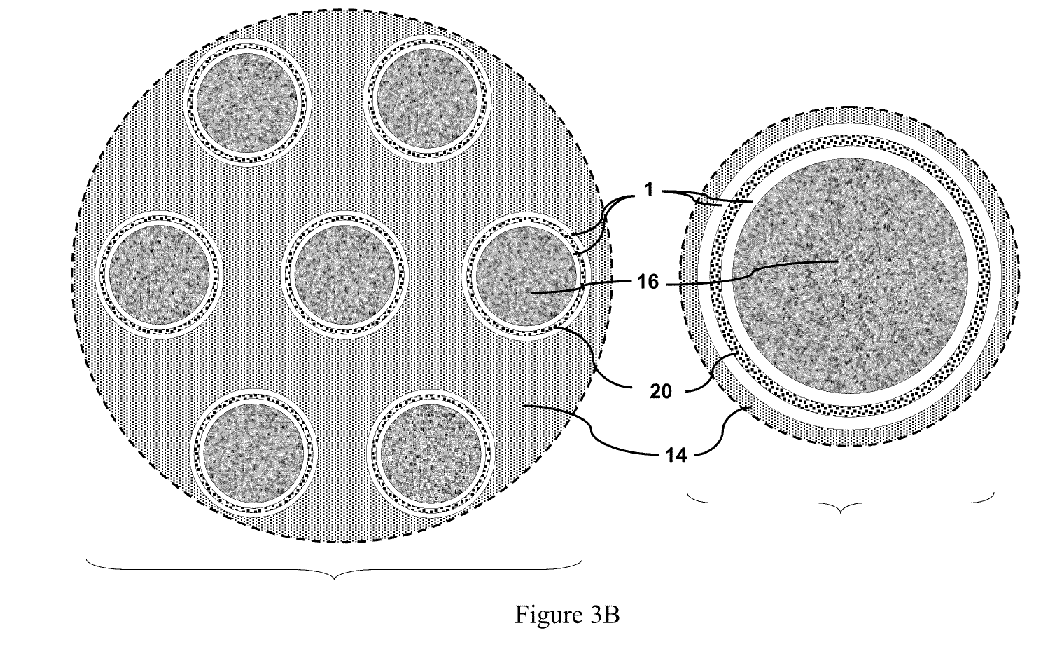

An exemplary die layout of the first side 2 of the Quantum Nanoporous Si Photodetector (QNPSPD) device 100 with plurality of dispersed isolated NPS island array regions 16 surrounded by a contiguous interconnected p/n junction region 14 forming the “Quantum Continuum” effective light absorbing region is shown in FIG. 3A. FIG. 3B shows an example of the details to construct by design an optimal pattern site placement distribution for the plurality of the dispersed isolated NPS island region array geometries of nc-pSi structure on the first side of the Quantum NPS Photodetector. A non limiting example includes circular NPS island regions 16 of nc-pSi structure having a pattern size with a diameter range of from about 0.5 um to about 50 um placed from about 1 um to about 100 um apart, with each NPS island region 16 placed in a non-limiting equidistant pattern distribution from each neighboring nc-pSi region along each perimeter. Alternative non-limiting geometrical shapes of the NPS island region pattern 16 include, oval, square, rectangle, polygon, cross, and triangle shapes. The plurality of isolated NPS region 16 pattern site distribution placement within the contiguous interconnected p/n junction surrounding region 14 can also be in any random configuration form. FIG. 3B shows also isolation trench rings 20 surrounding the plurality of each NPS island region shape 16 along each NPS perimeter with the same shape as the NPS island region and a trench ring width of from about 1 um to about 10 um with a separation gap distance from each nc-pSi island region structure of from about 0.5 um to about 20 um along each NPS perimeter. The outer perimeter of each trench ring isolation region 20 has a separation gap distance range from the surrounding contiguous p/n junction region 14 of from about 0.5 um to about 20 um. The lateral distance space gap range of each isolated NPS island region 16 from the surrounding contiguous p/n junction region 14 in a QNPSPD design version in the absence of a surrounding trench ring isolation region 20 is from about 1 um to about 300 um depending on the QNPSPD product design application specifications and reverse bias conditions.

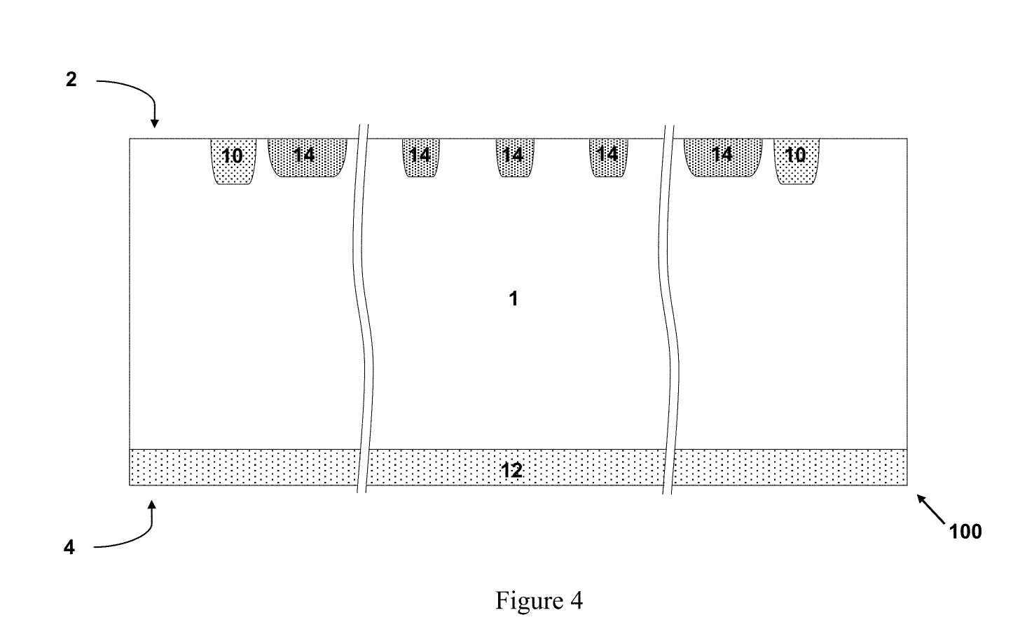

FIGS. 4 through 9 show the basic process steps and exemplary fabrication method of the structure of FIG. 2.

The exemplary basic QNPSPD fabrication process steps in creating the contiguous interconnected p/n junction region are shown in FIG. 4. The second side 4 is doped with a dopant of the first conductivity type via either ion implantation and/or Planar Solid Source dopant deposition to form a heavily doped back surface field (BSF) region 12 with a doping concentration of greater than or equal to about 1e18/cm³. Region 10 can also be formed at the same time when a Planar Solid Source dopant deposition is used to dope the back side, or alternatively it can be formed as a separate step doped with a dopant of the first conductivity type via ion implantation following the formation of the BSF region.

In one embodiment, a diffusion of the first conductivity type applied on the first side 2 of the high resistivity silicon substrate 1 in patterned regions 10 at the external perimeter of the QNPSPD with a doping concentration of greater than or equal to about 1e19/cm³. In this exemplary embodiment, a contiguous interconnected p/n junction region 14 as shown in FIGS. 3A & 3B is formed with a diffusion of the second conductivity type applied on the first side 2 with a doping concentration of greater than or equal to about 1e19/cm³ via a mask pattern that defines the p/n junction region by design based on QNPSPD application specification requirements. The interconnected p/n junction region forms the QNPSPD Photodetector Diode's total effective active area for collection of photogenerated carriers when the QNPSPD device 100 is illuminated from the first side 2. The doping concentration, doping depth profile, shape and size of the diffusion in p/n regions 14 may vary and it depends on the required QNPSPD photodetector application performance specification requirements. The thickness, resistivity range, and crystal orientation of the high resistivity silicon substrate may vary, and depends on the required QNPSPD photodetector performance requirements.

The BSF region 12 on second side 4 can act as a common Cathode or Anode for a vertical QNPSPD structure depending on the substrate conductivity type used. Region 10 on first side 2 can be formed at the same time with same diffusion and doping concentration applied in region 12, or it can alternatively be formed as a separate process step prior to formation of the contiguous interconnected p/n junction region 14. Region 10 can act as a “Channel Stop” and/or a lateral Cathode or Anode for a lateral coplanar QNPSPD structure, shown in FIG. 3A depending on the substrate conductivity type used and QNPSPD photodetector application performance requirements under specified reverse bias operation conditions.

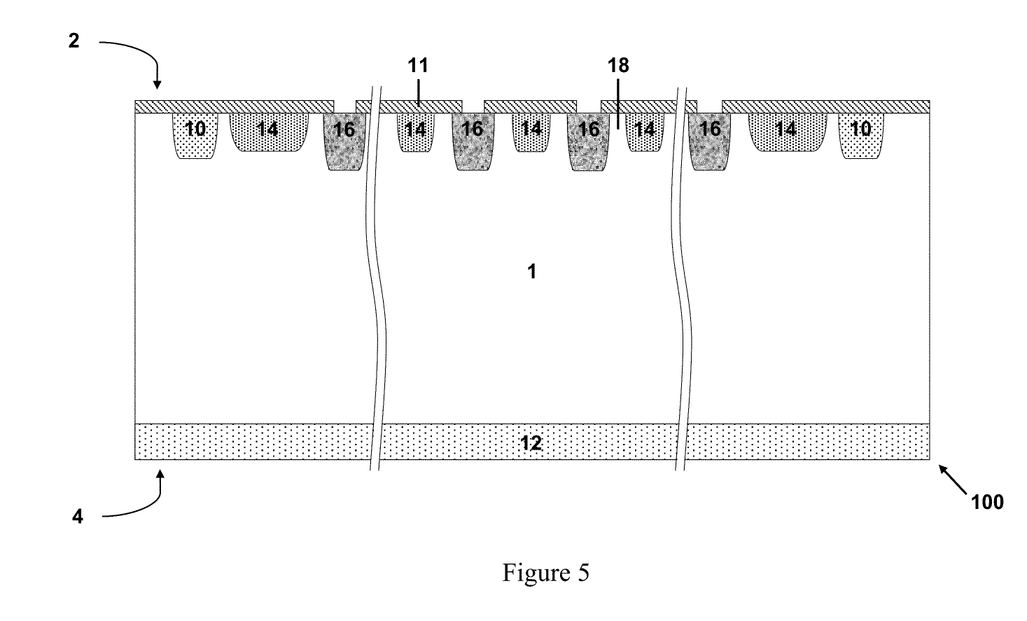

The next step of this exemplary QNPSPD device fabrication method is shown in FIG. 5. In an exemplary embodiment of this invention an NPS layer with a plurality of dispersed nc-pSi patterned island regions 16 is formed via selective porosification with sub 50 nm nanopores and nanocrystalline silicon skeleton (nc-Si) structure with randomly interconnected nanowire c-Si skeletons with a c-Si wire width range of from about 0.5 nm to about 50 nm on the first side 2 (top surface) of the substrate, wherein each NPS island 16 is surrounded by the contiguous interconnected p/n junction region 14 along its perimeter with pattern design details shown in FIGS. 3A and 3B forming a “Quantum Continuum” effective light absorbing region. The nc-pSi island patterned regions 16 are separated from the contiguous interconnected p/n junction region 14 with both regions disposed in the high resistivity Si substrate 1 with a separation gap 18. The depth and width of the dispersed plurality of nc-pSi island regions in the NPS array 16 disposed in the high resistivity Si substrate 1 and their corresponding separation gap distance 18 from the contiguous interconnected p/n junction region 14 may vary depending on the required QNPSPD photodetector performance specification requirements, peak wavelength light detection of interest, and reverse bias operating conditions. This fabrication process can have a non limiting exemplary NPS depth range for region 16 of from about 1 um to about 20 um with an NPS width range of from about 0.1 um to about 50 um and separation gap range distance 18 from the contiguous interconnected p/n junction region 14 of from about 1 um to about 100 um. The separation gap distance can be greater than 100 um depending on the application specification requirements and applied bias.

The porosity of the NPS island regions 16 and their corresponding nc-pSi nanowire skeleton structure is tunable when a non-limiting anodic electrochemical etching method is utilized as the preferred method for porosification via optimization of the electrochemical anodization parameters optimized for high resistivity silicon porosification. Non-limiting anodic electrochemical Si etching parameters for controlled NPS porosification include applied current density, and/or applied potential, and/or Hydrofluoric Acid (HF)/Solvent chemical mix ratio, and/or HF % concentration, and/or solvent concentration in an aqueous and/or non-aqueous (anhydrous) formulation, and/or surfactant wetting agent (like Triton X-100, and/or NCW-1001, or equivalent surfactant), and/or oxidizing agent (like Hydrogen Peroxide or equivalent oxidizer), with or without the presence of intense light illumination on the front side of the substrate and/or the back side of the substrate. The porosity of the NPS island regions of the QNPSPD device structure can be customized for optimization of the “Quantum Continuum” effective light absorbing region photodetection capability to extend up to about 1.55 um spectral range.

Layer 11 shown in FIG. 5 is a thermal oxide and/or other compatible material used as a hard mask during the porosification formation of the NPS islands 16 to define the plurality of dispersed distribution pattern sites of the NPS island array regions 16. A dopant species of either a neutral charge conductivity type, or first conductivity type, or second conductivity type, with doping concentration of equal or greater than 1e19/cm³ with a non-limiting high dose ion implantation method and/or alternate doping process method utilizing a BSG or PSG glass, designed to create shallow surface defects with shallow heavy doping, can be utilized at the surface of the open patterned high resistivity Si regions in substrate 1 in combination with the hard mask 11 to act as nucleation sites prior to anodic electrochemical etching for the selective controlled porosification of the plurality of the nc-Si island regions 16 in the high resistivity Si substrate during anodic electrochemical etching. A BSG glass, or equivalent “Acceptor” type dopant method, is preferred as the method for creating the surface defects as such a method also provides a positive charge dopant that further assists in the controlled anodic etch porosification of the dispersed distribution pattern sites of the NPS island array regions 16 in the high resistivity Si substrate.

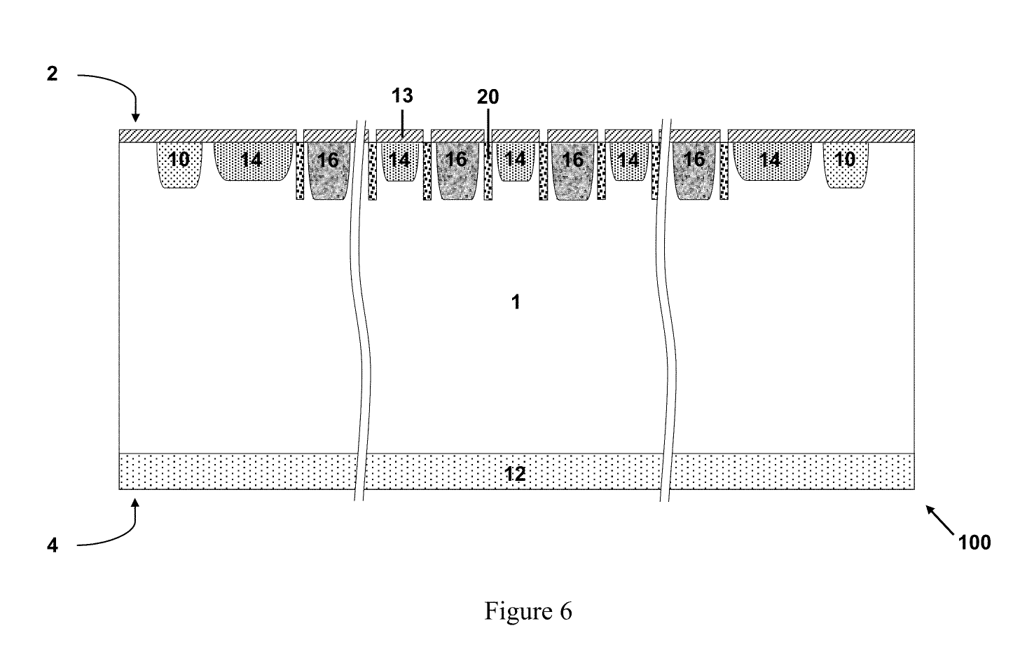

The next step of this exemplary QNPSPD device fabrication method is shown in FIG. 6, whereby a plurality of narrow trench ring isolation structure regions 20 are formed on the first side 2 (top surface) of the high resistivity Si substrate 1 with each trench structure surrounding each NPS island region 16 shape along its entire perimeter as shown in FIG. 3B. The trench rings 20 provide a lateral isolation of the plurality of nanoporous Si array island regions 16 along each island perimeter from the surrounding contiguous interconnected p/n junction region 14 on the first side 2 of the QNPSPD device when the device is operated in reverse bias so as the Space Charge Region (SCR) depletion width does not extend laterally to the side perimeter of the NPS island regions. The trenches may be created using dry etch (like RIE or DRIE, or equivalent reactive plasma etch), or wet etch, or other techniques known in the industry (like laser cut or pre-dice, or equivalent) with vertical or tapered side walls. The width of each trench structure may vary from about lum to about 10 um, and depends on the required QNPSPD photodetector performance specification requirements and reverse bias operating conditions. The depth of each trench structure 20 is preferably as deep as the NPS porosified region 16 depth and preferably not deeper than the NPS region depth so as the bottom region of the NPS is electrically interacting with the SCR region that can extend underneath the NPS structures under reverse bias operating conditions. Layer 13 shown in FIG. 6 is a low temperature CVD deposited dielectric material (like SiO2 and/or Si3N4), or other equivalent material, used as a hard mask during the trench isolation formation 20 to define the plurality of dispersed distribution pattern sites of the trench ring regions array.

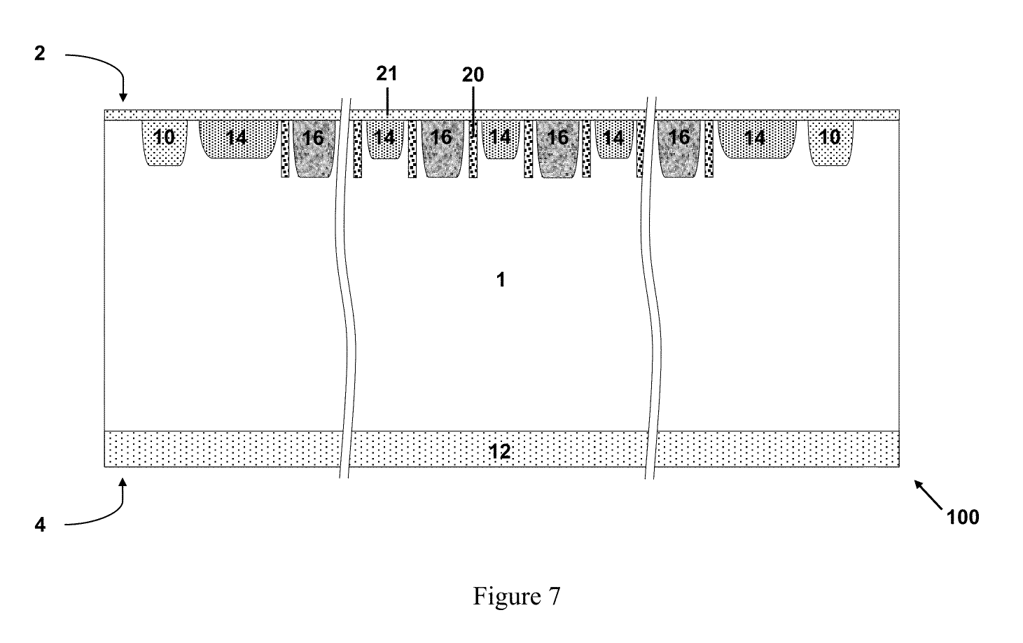

The next step in this exemplary QNPSPD device fabrication method is shown in FIG. 7, whereby a rapid thermal temperature heat treatment in an oxidizing environment that includes oxygen and/or nitrous oxide gas mixture with nitrogen and/or argon gas carrier can optionally be used to create a thin controlled SiO2 (RTO—SiO2), and/or a self limiting nitrided oxide (RTON—SiOxNy) layer 21. This exemplary passivating process step creates a stabilizing thin dielectric layer at the NPS porous surfaces of the formed nanocrystalline wire skeleton silicon wall structures of the dispersed NPS island array regions 16. It also passivates the walls of the trench ring regions 20 and serves as a passivation interface on the top surface of the QNPSPD for low surface leakage currents. The thickness of the RTO and/or RTONx layer 21 is preferably less than or equal to about 35 nm depending on the engineered porosity structure of the NPS regions designed based on the QNPSPD application specification requirements. This step can be performed also prior to the trench ring formation of regions 20.

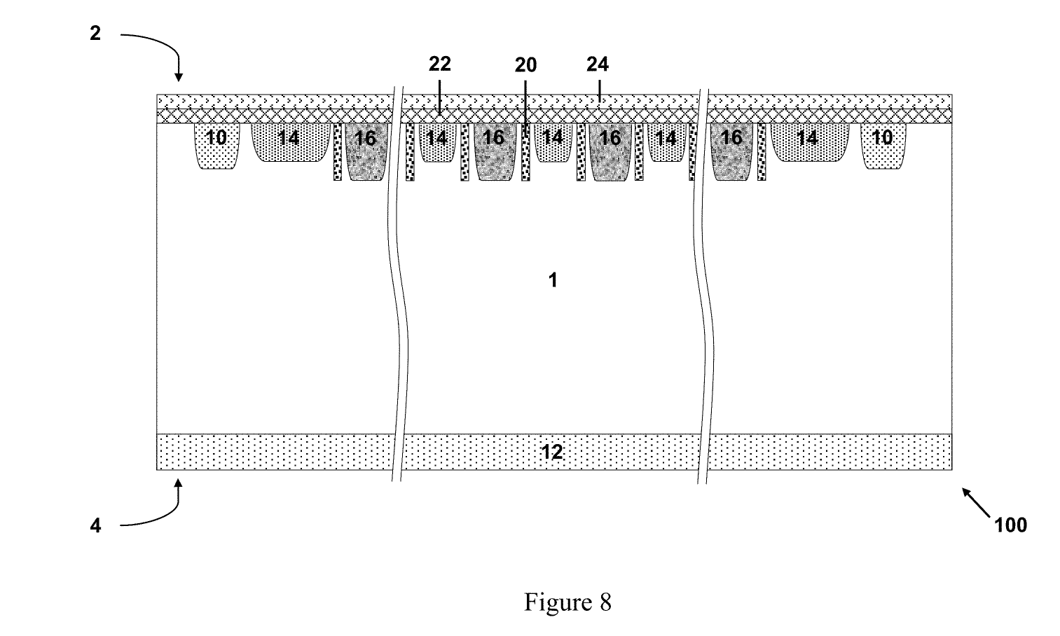

The next exemplary fabrication process step is shown in FIG. 8, where a silicon dioxide (SiO2) layer 22 is deposited via a non-limiting low temperature PECVD method and it is used as a final passivation interface antireflection coating (ARC) on the first side 2 of the QNPSPD Photodetector's surface with a deposition temperature range of from about 200° C. to about 350° C. to minimize any potential alteration on the nc-pSi structure in the NPS regions 16. The SiO2 layer 22 can either be deposited directly on the Si first side 2 surface, or on top of an optional thin RTO surface interface oxide when a Rapid Thermal Oxidation process step is used to create layer 21 to stabilize the NPS structure. A thin Si3N4 layer 24 may also be deposited via a non-limiting low temperature CVD method on top of the SiO2 layer 22 as a final capping layer for the NPS regions with a Si3N4 thickness that can be optimized to act as dual ARC layer on top of the contiguous interconnected p/n junction surface regions to obtain a high QE in the UV-Blue spectral region and/or maximize the peak wavelength range of interest depending on the QNPSPD application specification requirements. The NPS island regions are characterized by low reflectance properties throughout the entire spectral range, but suffer from a lower QE in the UV and Blue spectral range due to the shallow light absorption depth in these wavelengths with higher recombination rate in such regions. However, the QNPSPD device design with the dispersed plurality of NPS regions can take advantage of both the contiguous interconnected p/n junction diode region and plurality of dispersed NPS regions with an effective total active area characterized by a high QE performance of the QNPSPD throughout the entire spectral range. An enhanced UV-Blue responsivity with stable sensitivity can be obtained in the p/n junction region 14 via an optimized dual ARC layer thickness designed for the spectral range of from about 0.2 um to about 0.5 um with a QE greater than or equal to about 50% from about 0.25 um to about 0.30 um and greater than or equal to about 85% in the spectral range of from about 0.35 um to about 0.5 um. An enhanced Visible-Short NIR responsivity can be obtained via the NPS regions due to downward photoluminescence, quantum confinement, and low reflectance properties of the NPS structure resulting with a superior EQE performance of from about 0.5 um to about 1.1 um, with low noise and fast response time due to the deep depletion depth of the high resistivity Si substrate utilized.

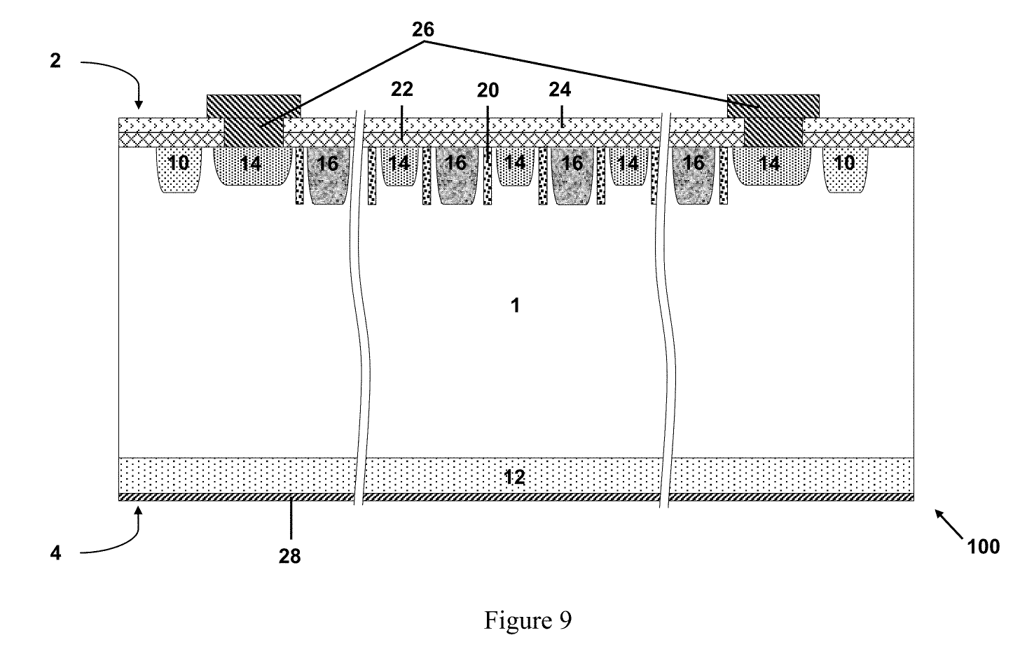

The result of the final exemplary basic fabrication steps of the Quantum Nanoporous Silicon Photodetector (QNPSPD) device structure 100 with plurality of dispersed trench isolated NPS island regions is shown in FIG. 9. In the final QNPSDP device structure 100, contacts are opened on the first side 2 of the high resistivity Si substrate 1 at the external perimeter of the contiguous interconnected p/n junction region 14 of second conductivity type to deposit and pattern a metal scheme to form contact pads 26 as shown in example of FIG. 3A. A metal scheme 28 is deposited on the second side 4. A suitable metallization scheme is utilized to create ohmic contacts on the corresponding doped Anode and Cathode regions of the high resistivity QNPSPD Photodetector depending on the device specification application requirements.

The QNPSPD device with high resistivity Si substrate can also be exposed to a moderate Sintering Temperature treatment in 350° C.-500° C. range in a gas environment that includes Argon, and/or Nitrogen, and/or Hydrogen, aiming to close the top surface nanopores of the NPS island regions following porosification and formation of the “Quantum Continuum” effective light absorbing region for enhanced device stability performance of the Quantum NPS Photodetector, either prior and/or after front metallization.

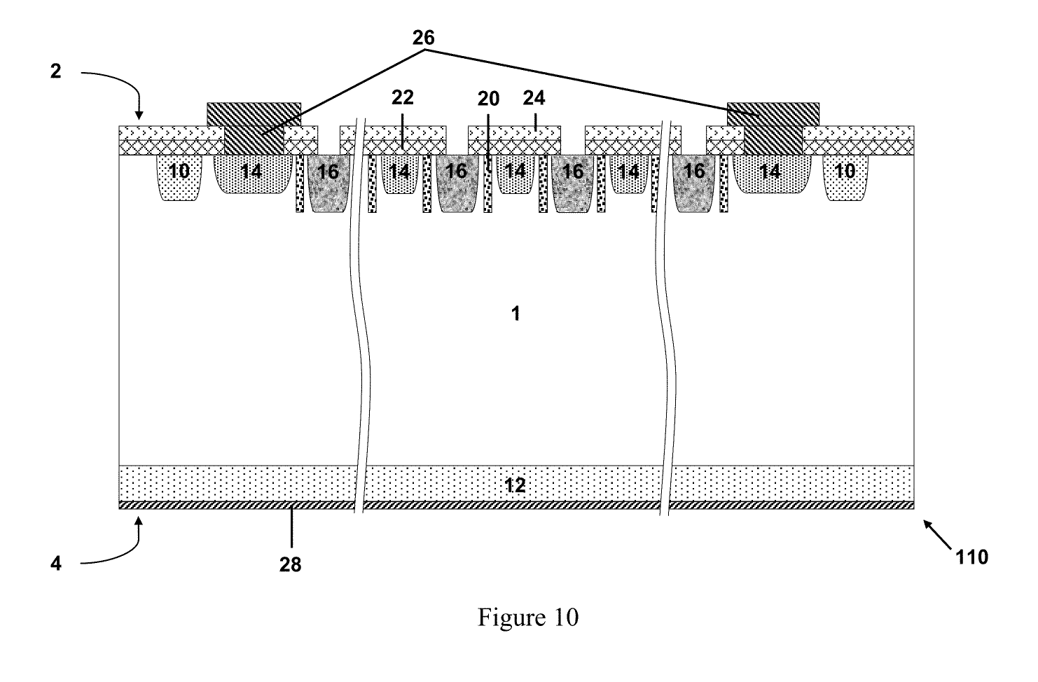

FIG. 10 shows an alternative fabrication process method of a QNPSPD Photodetector device 110 with a plurality of trench isolated nanoporous silicon array island regions 16 without RTO or RTONx passivation over the NPS island region structures 16. In this construction method the NPS island regions 16 are formed as the very last fabrication process step following front metal patterning of metal pads 16 and back metallization ohmic contact formation 28, simplifying the overall wafer fabrication manufacturing process for low cost construction and compatibility for manufacturing at a typical photonics wafer foundry fabrication facility designed for high yields. An additional technical advantage of this QNPSPD fabrication method is in providing a more uniform porosification of the plurality of dispersed NPS regions across the entire first side 2 of the high resistivity Si substrate 1 when anodic electrochemical etching is utilized as the preferred porosification method when back and front metallization is present on the QNPSPD wafer.

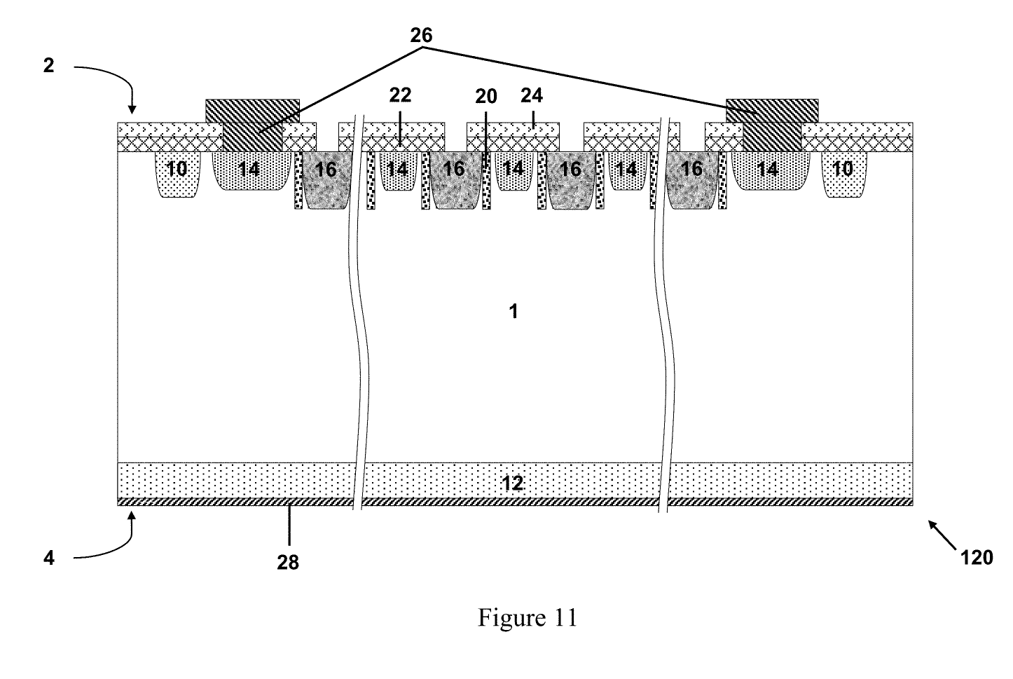

FIG. 11 shows another alternative fabrication process method of a QNPSPD Photodetector device structure 120 with a plurality of trench isolated nanoporous silicon array island regions 16 claiming same construction method benefits as the one described in FIG. 10 wherein the porosified regions in the dispersed NPS islands 16 extend to the side wall edges of the trench isolation regions 20 forming the “Quantum Continuum” effective light absorbing region.

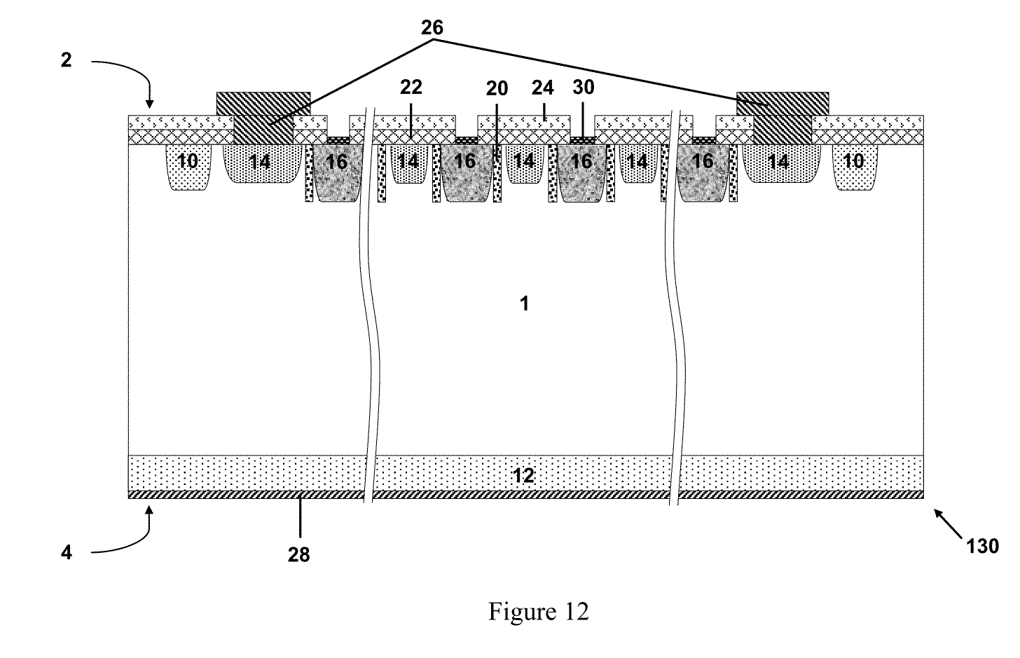

FIG. 12 shows yet another alternative fabrication process method of a QNPSPD Photodetector device 130 with a plurality of trench isolated nanoporous silicon array island regions 16 claiming same fabrication benefits as in FIG. 11 wherein RTO and/or RTONx regions 30 are formed selectively in the NPS regions 16 as the last step in the process flow following metallization of front side 2 and/or back side 4 surfaces with rapid thermal processing in the temperature range of from about 500° C. to about 800° C. for a time of from about 30 sec to about 300 sec in an oxidizing environment that includes oxygen and/or nitrous oxide gas mixture with nitrogen and/or argon gas carrier. In this version an exemplary metallization scheme can incorporate a Bi-Metal or Tri-Metal scheme that includes a metal silicide interface at the p/n junction contact regions (like TiSix or equivalent), and/or a metal diffusion barrier layer (like TiW, or TiWONx, or equivalent), and Gold (Au) top metal layer, to prevent metal migration and top metal pad oxidation during the RTO and/or RTONx post metallization heat treatment exposure that could affect the QNPSPD leakage current, diode forward voltage, breakdown voltage, and NEP performance.

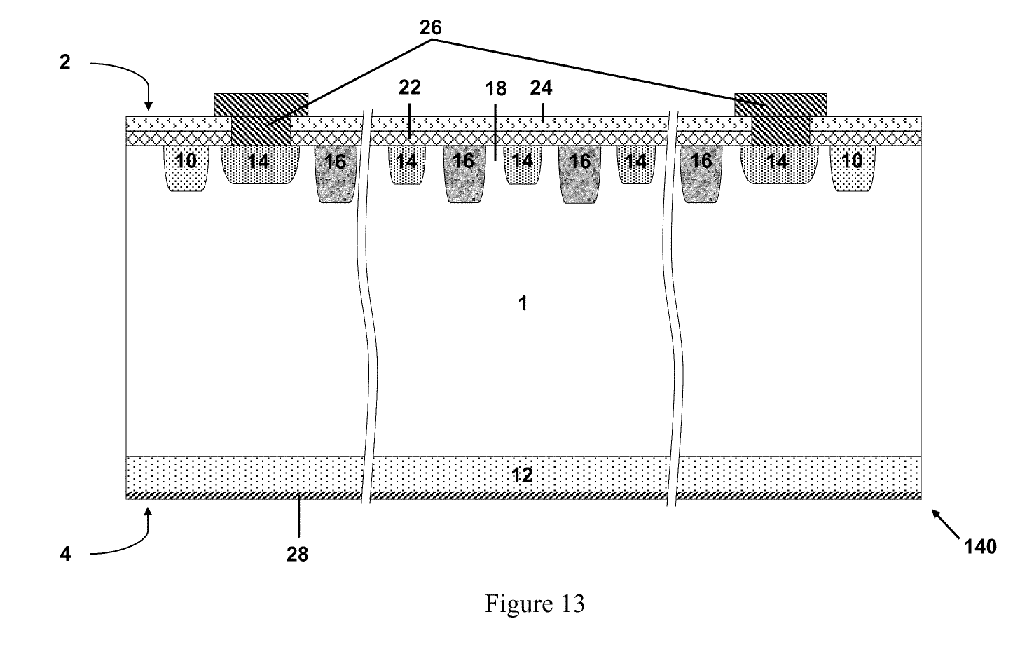

FIG. 13 shows another fabrication process method of a QNPSPD Photodetector device 140 without isolation trenches comparable to the one described in FIG. 9. In this QNPSPD device construction version the separation gap distance 18 between each NPS island region 16 and the surrounding contiguous interconnected p/n junction region 14 forming the “Quantum Continuum” effective light absorbing region is at least equal or greater to the Space Charge Region (SCR) depletion width determined by the high resistivity range of the Si substrate 1 and designed according the QNPSPD application specification under the specified reverse bias operating conditions. Such a QNPSPD Photodetector structure will be characterized by a higher leakage current and longer response fall time signal as compared to the trench isolation version of QNPSPD shown in FIG. 2 when operated in high reverse bias. However, such a QNPSPD device structure will exhibit a lower NEP, lower leakage currents and faster response time than prior art laser assisted microstructured Silicon Photodetectors as the p/n junction region is not in any direct contact with high leakage generating microstructures. This QNPSPD device construction method is better suited for Photovoltaic applications and/or low reverse bias applications, with a lower cost manufacturing benefit.

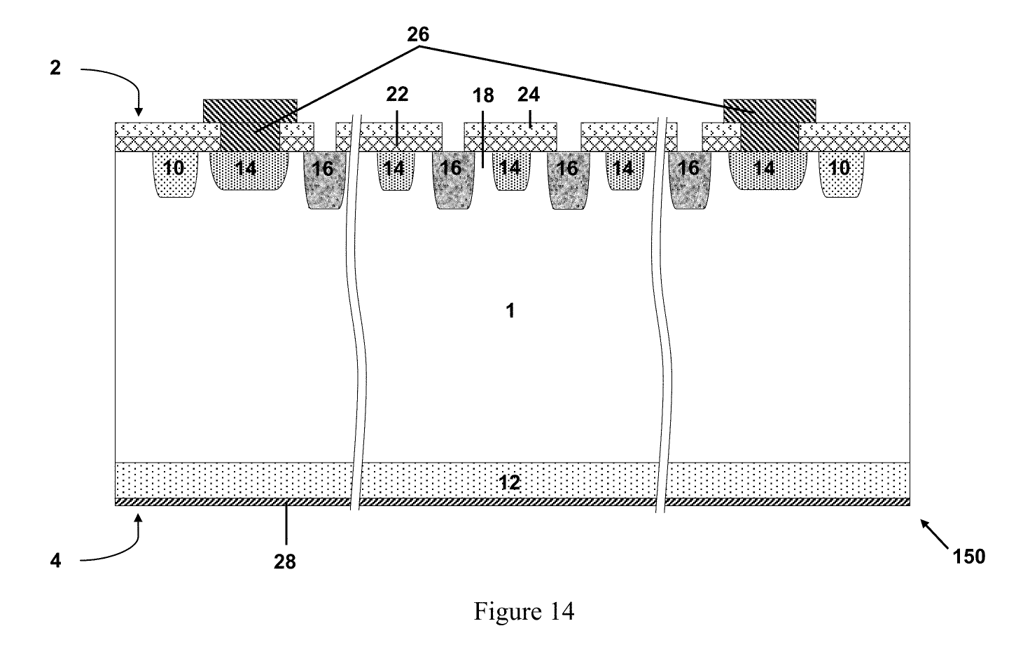

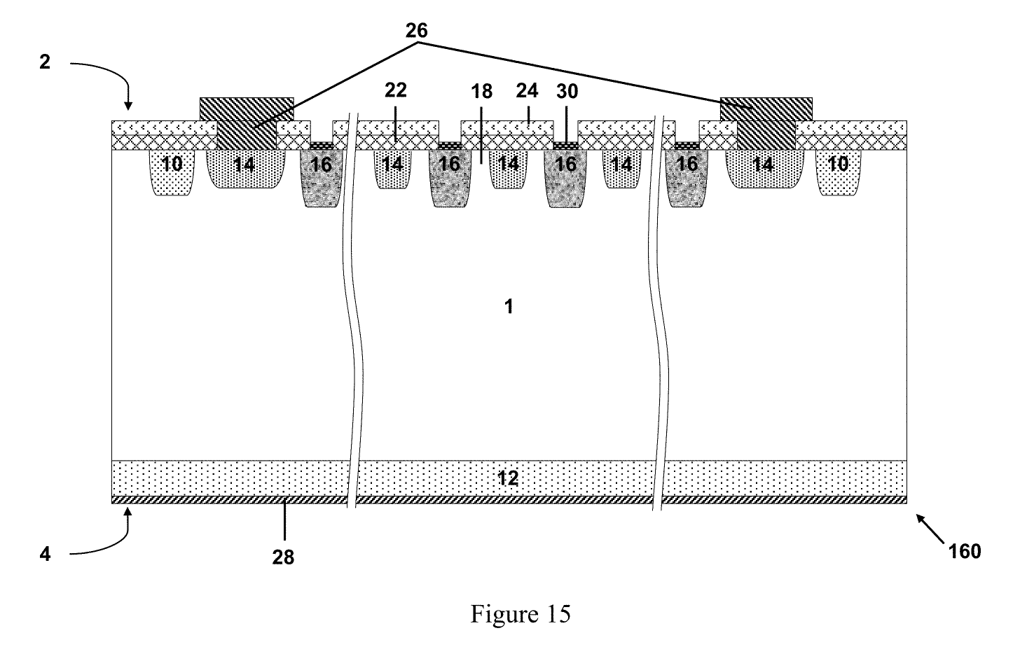

FIG. 14 and FIG. 15 show further alternative versions of the QNPSPD Photodetector device design structures 150 and 160 respectively without isolation trenches whereby the plurality of dispersed NPS regions 16 are formed after the front metal patterning and back metallization ohmic contact with same metallization schemes and post metallization fabrication process method benefit details as described in FIG. 10 and FIG. 12 respectively. This QNPSPD device construction method is better suited for Photovoltaic applications and/or low reverse bias applications, with a lower cost manufacturing benefit but with more stringent reliability performance requirements with regards to device performance stability under continuous operation.

The Quantum NPS Photodetector (QNPSPD) device structures described in this disclosure has a “Quantum Continuum” effective light absorbing region that can operate in the 0.2 um-1.1 um spectral range and it can be characterized by an enhanced responsivity in the UV, Visible, and short NIR light spectrum range of from about 0.2 um to about 1.1 um, with low leakage currents, low NEP, and fast PD response time performance for use in security, defense, medical imaging, and industrial sensor applications. The QNPSPD device structure described in this disclosure can operate at either in Photovoltaic mode at a bias of from about 0 V to about 100 mV, or in Photoconductive mode at a reverse bias up to about 180V. The QNPSPD device structure can be customized with device design optimization for photodetection capability in the 0.2 um to 1.55 um spectral range.

The current invention presents alternative device structures and fabrication methods of their preparation, which allow building Quantum NPS Photodetectors (QNPSPD) with superior device performance parameters utilizing construction methods that are scalable to large diameter wafer sizes including 150 mm, 200 mm, and up to 300 mm Dia, for low cost commercialization.

Note that although a <100> Si crystal orientation is preferred to be used for the manufacturing of the Quantum NPS Photodetector in this disclosure, either <100> or <111> Si crystal orientation may be used for the embodiments and objectives throughout this disclosure to construct a QNPSPD Photodetector device structure.

Note also that although P-Type Silicon (Si) substrate is preferred to be used for the manufacturing of the Quantum NPS Photodetector in this disclosure, as porosification of high resistivity conductivity P <100> Si is more adaptable to anodic electrochemical etching for controlled formation of the nanocrystalline porous silicon, an N-Type Si substrate may be used for the embodiments and objectives throughout this disclosure to construct a QNPSPD Photodetector device structure, wherein the mentioned doped regions are diffused with an opposite polarity conductivity type to form the Anode, Cathode, and BSF regions correspondingly to form the Quantum Continuum photodetection area.

Note that although a high resistivity hyper pure Si substrates with resistivity equal to or greater than 1,000 Ohm·cm is prefered for the manufacturing of the Quantum NPS Photodetector in this disclosure, high resistivity Si Substrates and/or high resistivity Epi-Si layers as low as 250 Ohm·cm can also be used for the embodiments and objectives throughout this disclosure to construct a QNPSPD Photodetector device structure as desired by custom Photodetector application specification requirements.

Note also that although anodic electrochemical etching is the preferred method to form a NPS layer with controlled porosity of the nc-pSi island regions and control of nc-Si skeleton wire size for better NPS region uniformity control and ease of manufacturing scalability to large size wafer diameters for low cost commercialization, the NPS layer regions can also be formed with alternative process technology methods. Alternative non-limiting methods for example can also include like stain chemical etching but at the expense of process control and uniformity, and/or use of e-beam lithography combined with selective RIE plasma based etching of the high resistivity Si material and backfilling any separation gaps between nc-Si skeleton wires with a passivating oxide at the expense of higher cost. The size of the nanocrystalline silicon skeleton wires can also be in a non-limiting size range of from about 0.1 nm to about 500 nm as disclosed in this invention and the nc-Si skeleton wires can be free standing in a predefined pattern distribution via a step-and-repeat pattern method when utilizing an e-beam method.

The QNPSPD device structures described in this disclosure can be monolithically integrated with PIC including waveguides, ROIC, CMOS, and/or ASICS for sensitive low light signal imaging.

While certain preferred embodiments and device construction methods of the present invention have been disclosed and described herein for purposes of illustration and not for purposes of limitation, it will be understood by those ordinary skilled in the art that various changes in form and detail may be made therein without departing from the spirit and scope of the invention. It is understood that this disclosure is not limited to the particular structures, process steps, or materials disclosed within, but it is extended to equivalents thereof, including but not limited to APD type QNPSPD. It should also be understood that the terminology employed herein is used for the purpose of describing particular embodiments and methods only and it is not intended to be limiting. It should also be understood that the referenced figures are for illustration purposes and are not to scale.

What is claimed is:

1. A Quantum NPS Photodetector (QNPSPD) device comprising:
a UV-VIS-NIR light absorbing high resistivity Silicon substrate of a first conductivity type having a first side and a second side;
a plurality of dispersed nanoporous Si array island regions formed from a first side of the high resistivity silicon (Si) substrate;
a contiguous interconnected p/n junction region of a second conductivity type being semiconductor doped formed from a first side of the high resistivity Si substrate surrounding the plurality of dispersed nanoporous Si island regions along the perimeter of each nanoporous Si island region and forming the photosensitive “Quantum Continuum” effective light absorbing region of the QNPSPD Photodetector;
a Back Surface Field (BSF) layer formed on the second side of the high resistivity semiconductor Si substrate being semiconductor doped with first conductivity type with high enough doping to provide an ohmic contact to the back side of the Quantum NPS Photodetector.

2. The Quantum NPS Photodetector of claim 1, wherein the high resistivity silicon substrate has a resistivity in the range of from about 250 Ohm·cm to about 1,000 Ohm·cm.

3. The Quantum NPS Photodetector of claim 1, wherein the high resistivity silicon substrate has a resistivity in the range of from about 1,000 Ohm·cm to about 20,000 Ohm·cm.

4. The Quantum NPS Photodetector of claim 1, wherein the high resistivity silicon substrate of a first conductivity type has a thickness in the range of from about 250 um to about 650 um.

5. The Quantum NPS Photodetector of claim 1, wherein the high resistivity silicon substrate of a first conductivity type is comprised of P <100> Type.

6. The Quantum NPS Photodetector of claim 1, wherein the high resistivity silicon substrate of a first conductivity type is comprised of P <111> Type.

7. The Quantum NPS Photodetector of claim 1, wherein the high resistivity silicon substrate of a first conductivity type is comprised of N<100> Type.

8. The Quantum NPS Photodetector of claim 1, further comprising a first conductivity type region being semiconductor doped from a first side of the substrate surrounding the outer perimeter of the contiguous interconnected p/n junction region.

9. The Quantum NPS Photodetector of claim 1, further comprising of a second conductivity type region being semiconductor doped from a first side of the substrate, surrounding the outer perimeter of the contiguous interconnected p/n junction region.

10. The Quantum NPS Photodetector of claim 1, wherein the Nanoporous Si island regions on the first side have a nanoporous Si layer thickness range of from about 0.1 um to about 50 um with a porosity range of from about 0.5 nm to about 50 nm and interconnected nanocrystalline Si wire skeletons with a c-Si wire width range of from about 0.5 nm to about 50 nm.

11. The Quantum NPS Photodetector of claim 1, wherein the plurality of dispersed nanocrystalline porous silicon (nc-pSi) island regions formed within the contiguous interconnected p/n junction region on the first side have a circular based geometry pattern with each nc-pSi island region having a diameter range of from about 0.5 um to about 50 um and placed from about 1 um to about 100 um apart in any dispersed pattern distribution formation.

12. The Quantum NPS Photodetector of claim 1, wherein the plurality of dispersed nanocrystalline porous silicon (nc-pSi) island regions formed within the contiguous interconnected p/n junction region on the first side have a rectangular based geometry pattern with each nc-pSi island region having a width range of from about 0.5 um to about 50 um and placed from about 1 um to about 100 um apart in any dispersed pattern distribution formation.

13. The Quantum NPS Photodetector of claim 1, wherein the plurality of dispersed nanocrystalline porous silicon (nc-pSi) island regions formed within the contiguous interconnected p/n junction region on the first side have a polygon based geometry pattern with each nc-pSi island region having a width range of from about 0.5 um to about 50 um and placed from about 1 um to about 100 um apart in any dispersed pattern distribution formation.

14. The Quantum NPS Photodetector of claim 1, wherein the plurality of dispersed isolated nanoporous Si island region array within the surrounding contiguous interconnected p/n junction region on the first side have an optimum packing density with each nanoporous Si island region being equidistant to each next neighboring nanoporous Si island region in any direction.

15. The Quantum NPS Photodetector of claim 1, wherein the nanocrystalline silicon skeleton wall surfaces of the NPS structure on the first side is passivated with a nitrided oxide (SiOxNy) via rapid thermal RTONx oxidation treatment in a reactive gas mixture containing nitrous oxide with a nitrided oxide layer thickness of from about 5 nm to about 35 nm.

16. The Quantum NPS Photodetector of claim 1, wherein the nanocrystalline silicon skeleton wall surfaces of the NPS structure on the first side is passivated with a silicon dioxide (SiO2) layer via rapid thermal oxidation (RTO) treatment in a reactive gas mixture containing very high purity oxygen with a SiO2 layer thickness of from about 5 nm to about 35 nm.

17. The method to manufacture the Quantum NPS Photodetector of claim 1, wherein the high resistivity Si substrate is selectively porosified on the first side to form a plurality of dispersed isolated nanoporous Si array island regions using a mask pattern with an anodic electrochemical etching method in a chemical solution mixture that includes an Electrolyte, a non-aqueous (anhydrous) solvent, a surfactant wetting agent, an oxidizing chemical agent, and applying an external current with a “potential” via electrodes to the high resistivity Si substrate in the presence of light illumination, whereby the porosity of the isolated nanoporous Si array island regions formed in the high resistivity Si substrate is tunable by varying the composition ratios of the aforementioned chemicals, applied current, potential, and illumination intensity.

18. A method of fabricating a Quantum NPS Photodetector comprising:
processing a high resistivity silicon substrate of first conductivity type with resistivity range of from about 250 Ohm·cm to about 20,000 Ohm·cm;
forming on a second side a layer doped with a first conductivity type with high enough doping concentration to form a Back Surface Field and provide an ohmic contact to the back side of the Quantum NPS Photodetector;
forming via mask patterning a semiconductor doped region of second conductivity type on first side surrounding the outer perimeter of the QNPSPD active area with a doping concentration of greater than or equal to about 1e19/cm³;
forming via mask patterning a contiguous interconnected p/n junction diode region on the first side of the high resistivity silicon substrate, wherein the p/n junction diode region is doped with second conductivity type with a doping concentration of greater than or equal to about 1e19/cm³, and wherein the p/n junction region is surrounding a plurality of dispersed island region patterns along the perimeter of each island region pattern shape, forming the photosensitive “Quantum Continuum” effective light absorbing region of the QNPSPD Photodetector;
forming nanoporous silicon (NPS) regions with a non-limiting anodic electrochemical etching process method via selective mask pattern porosification in the plurality of dispersed island region shapes formed on the first side, wherein the NPS island regions are characterized by a porosity of sub 50 nm nanopores and nanocrystalline silicon skeleton (nc-Si) structure with randomly interconnected nanowire c-Si skeletons of from about 0.5 nm to about 50 nm with a NPS depth range of from about 0.1 um to about 50 um, and wherein the NPS region shape has a width of from about 1 um to about 50 um with a separation gap distance range from the contiguous interconnected p/n junction region of from about 1 um to about 300 um;
applying a rapid thermal temperature heat treatment method in an oxidizing environment that includes oxygen, nitrous oxide gas mixture, and an inert carrier gas, wherein a thin controlled self limiting nitrided oxide (SiOxNy) layer with a thickness range of from about 5 nm to about 35 nm is formed on the surface of the nanoporous silicon regions and on the side walls of the nc-pSi nanowire skeleton structure to stabilize the optoelectronic properties of the NPS regions;
forming a top passivating dielectric cap region layer on the first side deposited via low temperature CVD at a temperature range of from about 200° C. to about 350° C., wherein the passivating layer acts as an antireflection coating (ARC) covering the entire contiguous interconnected p/n junction active area region surface, the plurality of dispersed nanoporous silicon island array region area surface, and covering the trench ring pattern side walls;
forming a Metal layer scheme suitable for ohmic contacts on the first side at contact opening locations at the perimeter of the contiguous interconnected photodetector diode junction on regions of second conductivity type patterned via a mask to form front metal pads on the QNPSPD;
forming a Metal layer scheme suitable for ohmic contact to the entire second back surface side;
applying a sintering treatment at a temperature range of from about 350 C to about 500° C. in a gas ambient that includes hydrogen and an inert gas to close the top surface nanopores of the NPS island regions and complete the fabrication process of the QNPSPD.

19. The Quantum NPS Photodetector method of claim 18, wherein the method includes a narrow trench ring pattern formed via RIE plasma etch on the first side surrounding the perimeter of each nanoporous silicon island region shape, wherein the trench ring width range is from about 1 um to about 10 um, and wherein the trench ring depth is not less than the depth of the surrounded nanoporous silicon island regions so as to provide electrical isolation from the contiguous interconnected p/n junction diode region;

20. An alternate method of fabricating a Quantum NPS Photodetector for low cost manufacturing adaptable to a standard wafer fabrication foundry processing and scalable to 200 um Dia wafers, comprising:
processing a high resistivity silicon substrate of first conductivity type with resistivity range of from about 250 Ohm·cm to about 20,000 Ohm·cm;
forming on a second side a layer doped with a first conductivity type with high enough doping concentration to form a Back Surface Field and provide an ohmic contact to the back side of the Quantum NPS Photodetector;
forming via mask patterning a semiconductor doped region of second conductivity type on first side surrounding the outer perimeter of the QNPSPD active area with a doping concentration of greater than or equal to about 1e19/cm³;
forming via mask patterning a contiguous interconnected p/n junction diode region on the first side of the high resistivity silicon substrate, wherein the p/n junction diode region is doped with the second conductivity type with a doping concentration of greater than or equal to about 1e19/cm³, and wherein the p/n junction region is surrounding a plurality of dispersed island region patterns along the perimeter of each island region pattern shape, forming the photosensitive “Quantum Continuum” effective light absorbing region of the QNPSPD Photodetector;
forming a top passivating dielectric antireflection coating (ARC) layer, wherein the ARC layer covers the entire contiguous interconnected p/n junction active area region surface;
forming a Tri-Metal scheme on the first side that includes a metal silicide interface at the interface with the p/n junction contact regions, a metal diffusion barrier middle layer, with a Gold (Au) top metal layer at contact opening locations at the perimeter of the contiguous interconnected photodetector p/n junction diode regions of second conductivity type patterned via a mask to form front metal pads on the QNPSPD device;
forming a Tri-Metal scheme on the second side that includes an Aluminum (Al) interface layer, a metal diffusion barrier middle layer, and a top metal layer of Gold (Au);
forming nanoporous silicon (NPS) regions following back metallization and front metal patterning with a non-limiting anodic electrochemical etching process method via selective mask pattern porosification, wherein a plurality of dispersed island regions is formed in the pattern shape locations defined on the first side surrounded by a contiguous interconnected p/n junction region, and wherein the NPS island regions are characterized by a porosity of sub 50 nm nanopores and nanocrystalline silicon skeleton (nc-Si) structure with randomly interconnected nc-Si wire skeletons having a nc-Si wire width range of from about 0.5 nm to about 50 nm with a NPS depth range of from about 0.1 um to about 50 um, wherein the NPS region shape has a width range of from about 1 um to about 100 um with a separation gap distance range from the contiguous interconnected p/n junction region of from about 1 um to about 300 um;
forming a self limiting nitrided oxide (SiOxNy) layer with a thickness range of from about 5 nm to about 35 nm on the surface walls of the nanocrystalline nc-pSi skeleton structure to stabilize the optoelectronic properties of the NPS regions via a rapid thermal temperature heat treatment method in an oxidizing environment that includes oxygen, nitrous oxide gas mixture, and an inert carrier gas to complete the fabrication process of the QNPSPD.
